(19) United States
(12) Patent Application Publication
(10) Pub. No.: US 2010/0164031 A1
(43) Pub. Date: Jul. 1, 2010

(54) IMAGE SENSOR AND MANUFACTURING METHOD THEREOF

(76) Inventor: Chang Yeop Shin, Incheon (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/629,250

(22) Filed: Dec. 2, 2009

(30) Foreign Application Priority Data
Dec. 31, 2008 (KR) 10-2008-0138791

(51) Int. Cl. H01L 31/0232; H01L 31/18

(52) U.S. Cl. 257/432; 438/69; 257/E31.127; 257/E21.536

(57) ABSTRACT

An image sensor and a manufacturing method thereof are provided. The image sensor according to an embodiment includes: a semiconductor substrate where a light receiving device is formed for each pixel; a dielectric layer formed on the semiconductor substrate; and a metal layer formed in the dielectric layer and including metal wires and light shielding patterns formed on an interface between pixels. In the image sensor according to the embodiment, since the light shielding pattern is formed by using a dummy pattern of the metal wire, the light shielding pattern may be formed close to the semiconductor substrate to minimize generation of optical leakage current, thereby improving reliability of the device.

### CROSS-REFERENCE TO RELATED APPLICATION

This application claims the benefit under 35 U.S.C. §119 of Korean Patent Application No. 10-2008-0138791, filed Dec. 31, 2008, which is hereby incorporated by reference in its entirety.

### BACKGROUND

An image sensor is a semiconductor device that converts an optical image into an electrical signal. Such image sensors generally include a charge coupled device (CCD) image sensor and a complementary metal oxide semiconductor (CMOS) image sensor.

The CMOS image sensor implements an image by sequentially detecting electrical signals of unit pixels through a switching scheme by forming a photodiode and a MOS transistor in each unit pixel.

There is a method of forming a microlens on a color filter in order to improve photosensitivity of the CMOS image sensor. The method forms the microlens in a spherical shape by sequentially exposing, developing, and reflowing a photosensitive organic material. Therefore, the microlens is formed on the unit pixels so as to focus light on the photodiode.

The microlens is formed for each unit pixel and the amount of incident light may vary depending on the size of the microlens and the number of the microlenses.

At this time, when the incident light is scattered on an interface of each interlayer dielectric layer or light is received in an area other than the microlens, leakage current is generated or noise is generated in an active area.

### BRIEF SUMMARY

An embodiment of the present invention provides an image sensor that forms a light shielding pattern by using a dummy pattern of a metal wire while forming the metal wires of an image sensor and a manufacturing method thereof.

An image sensor according to an embodiment includes: a semiconductor substrate where a light receiving device is formed for each pixel; a dielectric layer formed on the semiconductor substrate; and metal layer formed in the dielectric layer, the metal layer including metal wires and light shielding patterns formed at an interface between pixels.

A method of manufacturing an image sensor according to another embodiment includes: forming a light receiving device on a semiconductor substrate for each pixel; forming a circuit layer on the semiconductor substrate; forming a dielectric layer on the circuit layer; and forming a metal layer in the dielectric layer, wherein forming the metal layer includes forming metal lines and light shielding patterns on an interface between pixels.

### BRIEF DESCRIPTION OF THE DRAWINGS

FIGS. 1 to 3 are cross-sectional views showing a manufacturing process of an image sensor according to an embodiment of the present invention.

### DETAILED DESCRIPTION

An image sensor and a manufacturing method thereof according to an embodiment of the present invention will be described in detail with reference to the accompanying drawings.

In describing the embodiment, a case where an object is formed “on/over” layers, the term “on/over” includes both a case in which the object is formed directly on layers and a case in which the object is formed indirectly on layers (with another layer interposed therebetween).

In the drawings, thicknesses or sizes of layers may be exaggerated, omitted, or schematically illustrated for convenience and clarity of description. Further, sizes and actual sizes of constituent members are not fully reflected.

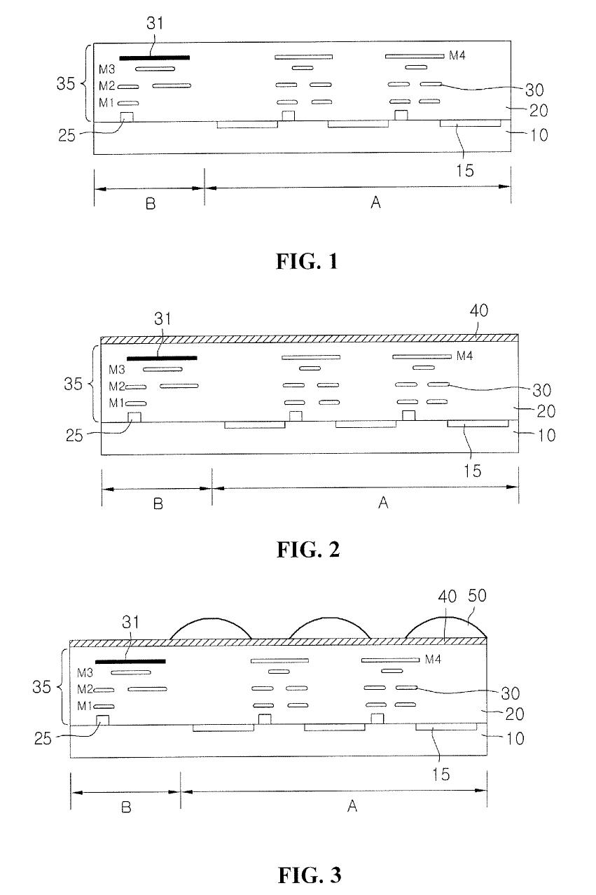

FIGS. 1 to 3 are cross-sectional views showing a manufacturing process of an image sensor according to an embodiment of the present invention.

Referring to FIG. 1, a pixel area A and a logic area B are formed on a semiconductor substrate 10.

The pixel area A includes a light receiving device 15 and a circuit layer 25 constituted by a transistor structure for processing photocharges generated in the light receiving device 15.

In one embodiment, the image sensor includes ion injection areas having a color filter structure in which photodiodes are vertically formed to detect colors. For example a red photodiode, a green photodiode, and a blue photodiode may be included and formed on the semiconductor substrate. In this case, three colors are vertically arranged in one pixel to implement a high-definition image. Further, various colors can be expressed by the light detecting device 15 without an additional color filter process. Further, the light receiving device may have a PN junction structure.

The image sensor according to another embodiment implements red, green, and blue pixels by forming a color filter layer below a microlens without forming the multiple light detecting device described above to express various colors.

The logic area B is used to process the photocharges generated in the pixel area A and may include a transistor structure (not shown).

A metal interconnect layer 35 can be formed on the semiconductor substrate 10. As part of the metal interconnect layer 35, metal layers M1, M2, M3, and M4 including metal wires 30, and an insulating layer 20 covering the metal wires 30 are formed on the semiconductor substrate 10 including the pixel area A and the logic area B.

The metal layers may include light shielding patterns 31.

The light shielding patterns 31 may be made of the same material as the top-layer metal wire 30 and formed as part of the same metal layer (M4) as the top-layer metal wire 30.

The light shielding pattern 31 is not electrically connected with the metal wires of metal layer M4 and the light shielding pattern 31 is separated from the metal wires of metal layer M4 formed on an interface of the pixel area, The light shielding pattern 31 can be formed on the top of the logic area B.

The metal wires 30 in metal layer M4 are electrically connected with lower transistors, while the light shielding pattern 31 is formed through patterning in the same process as the metal wires of metal layer M4, but is not electrically connected with peripheral circuits. The light shielding pattern 31 inhibits undesired light from being inputted into the active area of the semiconductor substrate 10.

Herein, the metal wires 30 are shown as formed on four different layers, but the number of metal layers are not limited to four and may be formed on various layers in accordance with the structure and characteristics of the image sensor.

The light shielding pattern 31 may be formed of a single layer or of double or triple layers by considering conductivity and a light shielding effect of the metal wire M4.

For example, the light shielding pattern 31 may include at least one of low-reflectance metallic materials including TiN and WSiₓ (Tungsten silicide). Further, the light shielding pattern 31 may further include an inorganic-based anti-reflection layer, and for example, may include SiON.

The inorganic-based anti-reflection layer may remain on the light shielding pattern 31 and the metal wires of the metal layer M4 without being removed due to excellent durability at the time of peeling a photoresist pattern in a photo process for forming the metal wires 30 and the light shielding pattern 31.

The light shielding pattern 31 may have a thickness of 1500 to 2000 Å.

While the light shielding pattern 31 is formed, the top-layer metal wire 30 is formed in the same process, made of the same material, and formed on the same layer (e.g., M4) as the light shielding pattern 31.

Other lower metal wires include at least one of metallic materials including aluminum (Al), tungsten (W), titanium (Ti), tantalum (Ta), copper (Cu), and molybdenum (Mo).

The image sensor according to the embodiment can facilitate a process and reduce lamination of an additional layer by forming a metal wire by using metal having low reflectance at the time of forming the metal wire 30 formed for a metal wire layer 35 and forming the light shielding pattern 31 in a light shielding area. That is, in the embodiment, since the process is simple, a yield increases, manufacturing cost is reduced, lamination of the additional layer decreases, thereby saving the manufacturing cost and improving optical efficiency.

In the image sensor according to an embodiment, since the light shielding pattern 31 is formed by using a dummy pattern of the metal wire 30, the light shielding pattern 31 may be formed close to the semiconductor substrate 10 to minimize generation of optical leakage current, thereby improving reliability of the device.

After the light shielding pattern 31 and the metal wire 30 of the top-layer metal layer M4 are formed, a top-layer interlayer dielectric layer or a passivation layer 40 is formed.

The passivation layer 40 may include at least one of an oxide layer, a nitride layer, and an oxynitride layer.

Microlenses 50 are formed on the passivation layer 40 to correspond to light receiving devices disposed for pixels, respectively. Light received through the microlens 50 is inputted into the light receiving device.

Before the microlenses 50 are formed, a color filter forming process may selectively be performed.

In the color filter forming process, a red color filter photoresist layer is formed on the passivation layer 40, and the red color filter photoresist layer is selectively exposed and developed to form a red color filter on the top of the corresponding pixel. Thereafter, after a blue color filter photoresist layer is formed on the passivation layer with the red color filter, the blue color filter photoresist layer is selectively exposed and developed to form a blue color filter on the top of the corresponding pixel. A green color filter can be formed on the passivation layer with the red and blue color filters by using the same method. Forming orders of the color filter layers may be combined and changed in various ways.

The image sensor according to an embodiment can facilitate a process and reduce lamination of an additional layer by forming a metal wire by using metal having low reflectance at the time of forming the metal wires of a metal wire layer and the light shielding pattern. That is, in the embodiment, since the process is simple, a yield increases, manufacturing cost is reduced, lamination of additional layers decreases, thereby saving the manufacturing cost and improving optical efficiency.

In the image sensor according to an embodiment, since the light shielding pattern is formed by using a dummy pattern of the metal wire, the light shielding pattern may be formed close to the semiconductor substrate to minimize generation of optical leakage current, thereby improving reliability of the device.

The foregoing present invention is not limited to the foregoing examples and the accompanying drawings. It will be apparent to those skilled in the art that various modifications and changes may be made without departing from the scope and spirit of the invention.

What is claimed is:

1. An image sensor, comprising:
a semiconductor substrate including a light receiving device formed for each pixel;
a dielectric layer formed on the semiconductor substrate; and
light shielding patterns formed in a metal wiring layer in the dielectric layer, the light shielding patterns being at an interface between pixels and separated from metal wires of the metal wiring layer.

2. The image sensor according to claim 1, further comprising:
a passivation layer formed on the dielectric layer, above the metal wires and the light shielding patterns; and
a microlens formed on the passivation layer to correspond to the light receiving device.

3. The image sensor according to claim 1, wherein the metal wires are electrically connected to a circuit layer on the semiconductor substrate.

4. The image sensor according to claim 1, wherein the light shielding pattern and the metal wires in the metal wiring layer are made of the same material.

5. The image sensor according to claim 1, wherein the light shielding pattern and the metal wires in the metal wiring layer include at least one of TiN and WSiₓ.

6. The image sensor according to claim 1, wherein the light shielding pattern and the metal wires in the wiring layer include an inorganic-based anti-reflection layer.

7. The image sensor according to claim 6, wherein the inorganic-based anti-reflection layer is SiON.

8. The image sensor according to claim 1, further comprising additional metal wiring layers in the dielectric layer below the metal wiring layer.

9. The image sensor according to claim 8, wherein metal wires formed in the additional metal wiring layers include at least one of Al, Ti, W, Mo, Cu, and Ta.

10. The image sensor according to claim 1, wherein thicknesses of the metal wires and the light shielding pattern in the metal wiring layer are 1500 to 2000 Å.

11. A method of manufacturing an image sensor, comprising:
forming a light receiving device on a semiconductor substrate for each pixel;
forming a circuit layer on the semiconductor substrate;
forming a dielectric layer on the circuit layer; and
forming a metal layer in the dielectric layer,
wherein the metal layer comprises metal wires and light shielding patterns formed on an interface between pixels, wherein the metal wires of the metal layer are electrically connected to the circuit layer and the light shielding patterns are dummy metal wires.

12. The method of manufacturing an image sensor according to claim 11, further comprising:
forming a passivation layer on the dielectric layer above the metal wires and the light shielding patterns; and
forming a microlens on the passivation layer to correspond to the light receiving device.

13. The method of manufacturing an image sensor according to claim 11, wherein the metal layer includes at least one of TiN and WSiₓ.

14. The method of manufacturing an image sensor according to claim 11, further comprising:
forming an inorganic-based anti-reflection layer on the metal layer,
wherein the anti-reflection layer remains on the metal wires and the light shielding patterns after patterning a metallic material forming the metal wires and the light shielding patterns.

15. The method of manufacturing an image sensor according to claim 11, further comprising forming additional metal layers in the dielectric layer below the metal layer, the additional metal layers comprising additional metal wires electrically connected with the circuit layer.

16. The method of manufacturing an image sensor according to claim 15, wherein the additional metal layers include at least one of Al, Ti, W, Mo, Cu, and Ta.
